(19) United States
(12) Patent Application Publication
(10) Pub. No.: US 2026/0289062 A1
(43) Pub. Date: Sep. 24, 2026

(54) PLACE AND ROUTE METHODOLOGIES FOR RESISTORS IN CMOS CIRCUITS

(71) Applicant: INTERNATIONAL BUSINESS MACHINES CORPORATION, ARMONK, NY (US)

(72) Inventors: MARCEL A. KOSSEL, REICHENBURG (CH); PIER ANDREA FRANCESE, ADLISWIL (CH); CARRIE ELLEN COX, APEX, NC (US); GLEN A. WIEDEMEIER, AUSTIN, TX (US)

(21) Appl. No.: 19/084,973

(22) Filed: Mar. 20, 2025

(51) Int. Cl. G06F 30/392; G06F 30/394

(52) U.S. Cl. CPC G06F 30/392; G06F 30/394

(57) ABSTRACT

Systems for place and route methodology integrating resistors into CMOS circuits includes: a processor, memory operatively coupled to the processor, and a place and route module included within the memory and configured to: determine that a CMOS circuit requires one or more resistors, determine, for each of the one or more resistors, a layout for a pcres device to include within the CMOS circuit, and add the one or more resistors to the CMOS circuit, including placing and routing, for each of the one or more resistors, components of the pcres device within the CMOS circuit.

### BACKGROUND

### Field of the Disclosure

The field of the disclosure is data processing, or, more specifically, methods, systems, and products for place and route methodology integrating polysilicon resistor (pcres) devices into complementary metal-oxide-semiconductor (CMOS) circuits.

### Description of Related Art

CMOS circuits primarily use transistors for logic functions. However, many circuit designs require the use of resistors (such as R-2R ladders, CML circuits, and the like). However, traditional CMOS layout methods are not compatible with resistors (especially resistive material (RM) resistors) due to differing design rules. This incompatibility has limited the use of automated layout tools (such as place and route methodologies) for these circuits, thereby hindering design efficiency and overall layout compactness.

### SUMMARY

Methods, apparatus, and systems for place and route methodology integrating resistors into CMOS circuits according to various embodiments are disclosed in this specification. In accordance with one aspect of the present disclosure, a method of place and route methodology integrating resistors into CMOS circuits includes determining, by a place and route module, that a CMOS circuit requires one or more resistors, determining, by the place and route module for each of the one or more resistors, a layout for a pcres device to include within the CMOS circuit, and adding the one or more resistors to the CMOS circuit, including placing and routing, for each of the one or more resistors, components of the pcres device within the CMOS circuit.

In accordance with another aspect of the present disclosure, a system for place and route methodology integrating resistors into CMOS circuits may include a processor, memory operatively coupled to the processor, and a place and route module included within the memory and configured to: determine that a CMOS circuit requires one or more resistors, determine, for each of the one or more resistors, a layout for a pcres device to include within the CMOS circuit, and add the one or more resistors to the CMOS circuit, including placing and routing, for each of the one or more resistors, components of the pcres device within the CMOS circuit.

The foregoing and other objects, features and advantages of the disclosure will be apparent from the following more particular descriptions of exemplary embodiments of the disclosure as illustrated in the accompanying drawings wherein like reference numbers generally represent like parts of exemplary embodiments of the disclosure.

### BRIEF DESCRIPTION OF THE DRAWINGS

FIG. 1 is a block diagram of an example system configured for place and route methodology integrating resistors into CMOS circuits in accordance with embodiments of the present disclosure.

FIG. 2 is a block diagram of an example computing environment configured for place and route methodology integrating resistors into CMOS circuits according to some embodiments of the present disclosure.

FIG. 3 is a block diagram of an example power bay comprising a CMOS circuit integrating resistors using place and route methodology according to some embodiments of the present disclosure.

FIG. 4 is a flowchart of an example method for place and route methodology integrating resistors into CMOS circuits according to some embodiments of the present disclosure.

FIG. 5 is a flowchart of another example method for place and route methodology integrating resistors into CMOS circuits according to some embodiments of the present disclosure.

### DETAILED DESCRIPTION

In accordance with one aspect of the present disclosure, a method of place and route methodology integrating resistors into CMOS circuits may include determining, by a place and route module, that a CMOS circuit requires one or more resistors; determining, by the place and route module for each of the one or more resistors, a layout for a pcres device to include within the CMOS circuit; and adding the one or more resistors to the CMOS circuit, including placing and routing, for each of the one or more resistors, components of the pcres device within the CMOS circuit. Such an embodiment allows for increased circuit efficiency by allowing for CMOS style layouts that include resistors without having to rely on less compact RM resistors.

In another embodiment, the pcres device is added to a CMOS power grid bay comprising the CMOS circuit. Such an embodiment provides increased circuit efficiency by including, using a place and route program, pcres resistors within a CMOS circuit while sharing a power grid.

In another embodiment, determining the layout for the pcres device includes defining one or more layout ports for the pcres device on one or more routing tracks being used by other components of the CMOS circuit. Such an embodiment provides a method of determining where to place one or more ports for each pcres device, where the placement on the power grid of the ports may affect the overall resistance value of the pcres device.

In another embodiment, the layout of the pcres device is determined based on one or more layout parameters. Such an embodiment provides multiple different ways to determine how to place and design the layout of a CMOS circuit that includes pcres devices.

In another embodiment, the one or more layout parameters includes a number of parallel rm stripes and a meander length of the pcres device. Such an embodiment provides a mechanism to add resistance to the overall resistance value of the pcres device, such as through using parallel stripes (interacting with the power grid on which the CMOS circuit is placed).

In another embodiment, the one or more layout parameters includes a selection of an implant below the pcres stripes to approximate a desired resistance value. Such an embodiment provides a mechanism to add resistance to the overall resistance value of the pcres device.

In another embodiment, the method further includes calculating a resistance value for the pcres device based on the one or more layout parameters. Such an embodiment provides a means for checking the performance or accuracy of the designed pcres device.

In another embodiment, the place and route module is configured to provide suggested layout parameters based on a desired resistance value. Such an embodiment provides a method of determining how to design a pcres device within a specific CMOS circuit based on given resistance requirement.

In another embodiment, the layout of the pcres device is determined based on a resistive material to be included within the one or more resistors. Such an embodiment provides a method that considers, selects, or takes into account one or more resistive materials available for the pcres device when designing the device and the CMOS circuit as a whole.

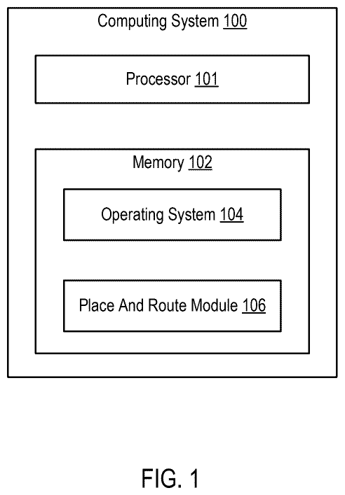

Exemplary methods, systems, and products for place and route methodology integrating resistors into CMOS circuits in accordance with the present disclosure are described with reference to the accompanying drawings, beginning with FIG. 1. FIG. 1 sets forth a block diagram of an example system configured for place and route methodology integrating resistors into CMOS circuits in accordance with embodiments of the present disclosure. The example of FIG. 1 includes computing system 100, which includes at least one processor 101, and memory 102. The example memory 102 is operatively coupled to the processor 101 and includes an operating system 104 and a place and route module 106.

The example place and route module 106 is configured to aid in the design of CMOS circuits by performing various steps of place and route methods. A CMOS (Complementary Metal-Oxide-Semiconductor) circuit is a type of electronic circuit that uses both P-type and N-type MOSFETs (Metal-Oxide-Semiconductor Field-Effect Transistors) to implement logic gates and other digital circuits. Some examples of common CMOS circuits include basic logic gates (such as inverters, AND gates, NAND gates, OR gates, NAND gates, NOR gates), flip-flops, adders, registers, memory cells, microprocessors, and the like. While transistors are the primary components in CMOS circuits, resistors are sometimes employed to achieve specific functionalities, especially in analog CMOS circuits. Some examples of CMOS circuits that may require resistors include biasing circuits (used to set specific voltage levels or current biases for transistors), current limiting circuits (used to limit the amount of current flowing through a particular circuit path), filtering circuits (using resistors with capacitors to filter out unwanted frequencies in analog circuits), sense amplifiers (used to amplify small voltage differences), R2R ladders (used to convert digital signals into analog signals), current mode logic (CML) circuits (a high-speed digital circuit that switches current between different paths to represent logic states), and many others.

Such CMOS circuits are designed and manufactured using a complex process. One step in the design process of CMOS circuits includes using place and route methods. Place and route is a critical step in the design of CMOS circuits and involves two key stages: the automated placement of individual transistors and other components on a silicon die, followed by the routing of wires to connect these components. A crucial aspect of the place and route process is the design and consideration of the power grid (on which the CMOS circuit is positioned). A well-designed power grid ensures reliable power distribution to all components on the chip. The power grid (or ‘power bay’) typically consists of multiple layers of metal interconnects (such as wires and vias), with wider metal layers used for power supply rails. For example, a typical power grid runs with the odd-numbered metals in the horizontal direction and with the even-numbered metals in the vertical direction. This creates a grid, with vias connecting the different metal levels in the grid points. The smallest unit of the grid, i.e. a single mesh of the grid, is called a power bay. The layout of CMOS logic circuits is designed to fit into a power bay. The distribution and routing of these devices can then be done using place and route methodologies. The same is to be applied to pcres devices. Decoupling capacitors may be strategically placed to filter out noise and stabilize voltage levels. The placement of components and the routing of wires must be carefully planned to minimize signal delays, reduce power consumption, and avoid interference between different signals. Place and route tools rely on advanced algorithms to optimize these factors and generate a circuit layout that meets the performance and area constraints of the circuit design.

While place and route methodologies are conventionally used to design conventional transistor CMOS circuits, the place and route (P&R) design methodology has been incompatible for use when designing CMOS circuits that also include resistors of the type of RM resistors. Thus far, the inclusion of resistors into CMOS circuits made a compact CMOS design using P&R methodologies impossible because RM resistors (i.e., a passive device made of a RM layer where the resistance value is determined by its width and length) are incompatible to regular CMOS style layout (e.g., alternating n-fet and p-fet implants, with power delivery via power grids). Thus, CMOS circuitries that include resistors could neither benefit from P&R methods nor from the inherent layout compactness of a CMOS layout style (i.e., power grids with n-/p-implant regions).

Conventionally, place and route methodology has not had a place for rmres (RM resistors) devices in CMOS style layouts because the ground rules of rmres devices are so different from those of transistors found in CMOS circuits. Part of the problem with RM resistors is that they require spacing rules from FET devices, which prevent RM resistors from being included into CMOS power bays. Only pcres devices or other resistive material compatible to CMOS layout style (i.e., resistive materials also used in fets such as pc, ca, cm, mx) enable the implementation of P&R methodologies for a seamless integration of those resistive materials in CMOS style layouts. The availability of a P&R methodology that includes rm shapes may provide a significant improvement to perform CMOS style layouts including resistors in a semi-automated or even automated fashion (for a more compact design, less parasitics, less time to complete the layout).

In the present disclosure, the term “rm” refers to the entirety of all resistive materials (e.g., pc stripes, CM or CA of the front-end-of-the line (FEOL) shapes (plus the lowest M1 metal of the back-end-of-line (BEOL) shapes)) and “RM” (capital letters) refers to the conventional implementation of an RM resistor. A conventional RM resistor does not fit into a Power Bay and hence is not suitable for place and route methodologies.

The present disclosure describes the replacement of conventional RM resistors with rmres devices by resistive material (i.e., resistors made of resistive material whose layout shapes such as CA, PC (polysilicon), Mx are compatible to that of n-fets and p-fets—which is different from conventional RM resistors) and configure them such that they can be handled easily by P&R methodologies enabling a seamless integration into a compact CMOS style layout. This reduces not only the physical design work, but may also reduce capacitive and resistive parasitic effects because such a method no longer requires the extra routing necessary between CMOS transistors and RM resistors. These improvements are particularly apparent in the most recent leading edge CMOS technologies (e.g., 14 nm-5 nm finfet and <3 nm gate-all-around). The present disclosure describes various embodiments for integrating rmres devices into P&R methodologies for use in CMOS style circuits. Note, pcres devices are used throughout this disclosure, which refers to polysilicon resistor devices. However, a pcres device is only one of multiple other rmres devices that may be used throughout this disclosure in place of pcres devices, because this disclosure relies on the replacement of conventional RM resistors with various rmres devices using various resistive materials (one of which is PC or polysilicon). In other embodiments, the described pcres devices may include materials other than polysilicon, such as CA, CM, Mx, etc. However, for ease of explanation, the term pcres will be used to describe any rmres (a device containing any resistive material) configured to replace a conventional RM resistor in order to be seamlessly integrated into the place and route methodologies for designing CMOS circuits.

The present disclosure describes various embodiments for integrating rmres devices into P&R methodologies for use in CMOS style circuits. Such embodiments are carried out by place and route module 106 of FIG. 1, where such embodiments include parametrizing pcres devices to fit into regular CMOS power bays (power grids), providing pcres device terminals on the same metal grid as those of inverters and logical gates, and ultimately making pcres devices configurable such that the resistance value required is approximated best by the pertinent selection of various layout parameters, such as the port placement, the number of parallel rm stripes, the length of the rm meanders and—if applicable—also the choice of the implant underneath the rm stripe (e.g., swallow-trench isolation, n-fet implant, and p-fet implant).

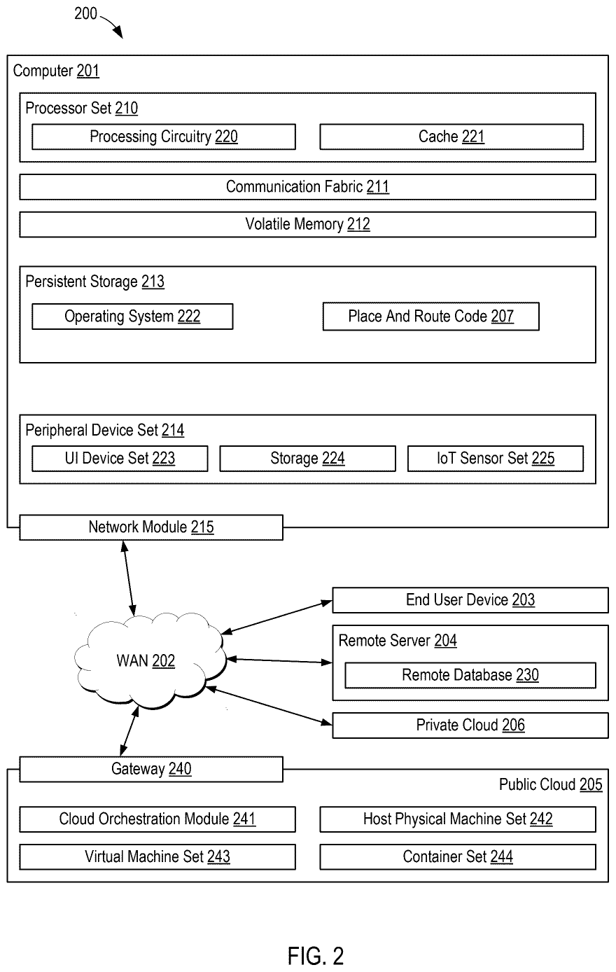

For further explanation, FIG. 2 sets forth a block diagram of computing environment 200 configured for place and route methodology integrating resistors into CMOS circuits in accordance with embodiments of the present disclosure. Computing environment 200 contains an example of an environment for the execution of at least some of the computer code involved in performing the inventive methods, such as place and route code 207 or operating system 222. In addition to place and route code 207, computing environment 200 includes, for example, computer 201, wide area network (WAN) 202, end user device (EUD) 203, remote server 204, public cloud 205, and private cloud 206. In this example embodiment, computer 201 may include the computing system 100 shown in FIG. 1, and includes processor set 210 (including processing circuitry 220 and cache 221), communication fabric 211, volatile memory 212, persistent storage 213 (including operating system 222 and place and route code 207, as identified above), peripheral device set 214 (including user interface (UI) device set 223, storage 224, and Internet of Things (IoT) sensor set 225), and network module 215. Remote server 204 includes remote database 230. Public cloud 205 includes gateway 240, cloud orchestration module 241, host physical machine set 242, virtual machine set 243, and container set 244. In one embodiment, the place and route code 207 is included in the place and route module 106 and is configured to analyze the defect database, determine an update to parameters, and send the update to the system. In another embodiment, the place and route code 207 is included within the operating system 222.

Computer 201 may take the form of a desktop computer, laptop computer, tablet computer, smart phone, mainframe computer, quantum computer or any other form of computer or mobile device now known or to be developed in the future that is capable of running a program, accessing a network or querying a database, such as remote database 230. As is well understood in the art of computer technology, and depending upon the technology, performance of a computer-implemented method may be distributed among multiple computers and/or between multiple locations. On the other hand, in this presentation of computing environment 200, detailed discussion is focused on a single computer, specifically computer 201, to keep the presentation as simple as possible. Computer 201 may be located in a cloud, even though it is not shown in a cloud in FIG. 2. On the other hand, computer 201 is not required to be in a cloud except to any extent as may be affirmatively indicated.

Processor set 210 includes one, or more, computer processors of any type now known or to be developed in the future. Processing circuitry 220 may be distributed over multiple packages, for example, multiple, coordinated integrated circuit chips. Processing circuitry 220 may implement multiple processor threads and/or multiple processor cores. Cache 221 is memory that is located in the processor chip package(s) and is typically used for data or code that should be available for rapid access by the threads or cores running on processor set 210. Cache memories are typically organized into multiple levels depending upon relative proximity to the processing circuitry. Alternatively, some, or all, of the cache for the processor set may be located “off chip.” In some computing environments, processor set 210 may be designed for working with qubits and performing quantum computing.

Computer readable program instructions are typically loaded onto computer 201 to cause a series of operational steps to be performed by processor set 210 of computer 201 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 221 and the other storage media discussed below. The program instructions, and associated data, are accessed by processor set 210 to control and direct performance of the inventive methods. In computing environment 200, at least some of the instructions for performing the inventive methods may be stored in place and route code 207 in persistent storage 213.

Communication fabric 211 is the signal conduction path that allows the various components of computer 201 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

Volatile memory 212 is any type of volatile memory now known or to be developed in the future. Examples include dynamic type random access memory (RAM) or static type RAM. Typically, volatile memory 212 is characterized by random access, but this is not required unless affirmatively indicated. In computer 201, the volatile memory 212 is located in a single package and is internal to computer 201, but, alternatively or additionally, the volatile memory may be distributed over multiple packages and/or located externally with respect to computer 201.

Persistent storage 213 is any form of non-volatile storage for computers that is now known or to be developed in the future. The non-volatility of this storage means that the stored data is maintained regardless of whether power is being supplied to computer 201 and/or directly to persistent storage 213. Persistent storage 213 may be a read only memory (ROM), but typically at least a portion of the persistent storage allows writing of data, deletion of data and re-writing of data. Some familiar forms of persistent storage include magnetic disks and solid state storage devices. Operating system 222 may take several forms, such as various known proprietary operating systems or open source Portable Operating System Interface-type operating systems that employ a kernel. The code included in place and route code 207 typically includes at least some of the computer code involved in performing the inventive methods.

Peripheral device set 214 includes the set of peripheral devices of computer 201. Data communication connections between the peripheral devices and the other components of computer 201 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 223 may include components such as a display screen, speaker, microphone, wearable devices (such as goggles and smart watches), keyboard, mouse, printer, touchpad, game controllers, and haptic devices. Storage 224 is external storage, such as an external hard drive, or insertable storage, such as an SD card. Storage 224 may be persistent and/or volatile. In some embodiments, storage 224 may take the form of a quantum computing storage device for storing data in the form of qubits. In embodiments where computer 201 is required to have a large amount of storage (for example, where computer 201 locally stores and manages a large database) then this storage may be provided by peripheral storage devices designed for storing very large amounts of data, such as a storage area network (SAN) that is shared by multiple, geographically distributed computers. IoT sensor set 225 is made up of sensors that can be used in Internet of Things applications. For example, one sensor may be a thermometer and another sensor may be a motion detector.

Network module 215 is the collection of computer software, hardware, and firmware that allows computer 201 to communicate with other computers through WAN 202. Network module 215 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 215 are performed on the same physical hardware device. In other embodiments (for example, embodiments that utilize software-defined networking (SDN)), the control functions and the forwarding functions of network module 215 are performed on physically separate devices, such that the control functions manage several different network hardware devices. Computer readable program instructions for performing the inventive methods can typically be downloaded to computer 201 from an external computer or external storage device through a network adapter card or network interface included in network module 215. Network module 215 may be configured to communicate with other systems or devices, such as sensors 225, for receiving sensor measurements.

WAN 202 is any wide area network (for example, the internet) capable of communicating computer data over non-local distances by any technology for communicating computer data, now known or to be developed in the future. In some embodiments, the WAN 202 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 203 is any computer system that is used and controlled by an end user (for example, a customer of an enterprise that operates computer 201), and may take any of the forms discussed above in connection with computer 201. EUD 203 typically receives helpful and useful data from the operations of computer 201. For example, in a hypothetical case where computer 201 is designed to provide a recommendation to an end user, this recommendation would typically be communicated from network module 215 of computer 201 through WAN 202 to EUD 203. In this way, EUD 203 can display, or otherwise present, the recommendation to an end user. In some embodiments, EUD 203 may be a client device, such as thin client, heavy client, mainframe computer, desktop computer and so on.

Remote server 204 is any computer system that serves at least some data and/or functionality to computer 201. Remote server 204 may be controlled and used by the same entity that operates computer 201. Remote server 204 represents the machine(s) that collect and store helpful and useful data for use by other computers, such as computer 201. For example, in a hypothetical case where computer 201 is designed and programmed to provide a recommendation based on historical data, then this historical data may be provided to computer 201 from remote database 230 of remote server 204.

Public cloud 205 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 205 is performed by the computer hardware and/or software of cloud orchestration module 241. The computing resources provided by public cloud 205 are typically implemented by virtual computing environments that run on various computers making up the computers of host physical machine set 242, which is the universe of physical computers in and/or available to public cloud 205. The virtual computing environments (VCEs) typically take the form of virtual machines from virtual machine set 243 and/or containers from container set 244. It is understood that these VCEs may be stored as images and may be transferred among and between the various physical machine hosts, either as images or after instantiation of the VCE. Cloud orchestration module 241 manages the transfer and storage of images, deploys new instantiations of VCEs and manages active instantiations of VCE deployments. Gateway 240 is the collection of computer software, hardware, and firmware that allows public cloud 205 to communicate through WAN 202.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 206 is similar to public cloud 205, except that the computing resources are only available for use by a single enterprise. While private cloud 206 is depicted as being in communication with WAN 202, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 205 and private cloud 206 are both part of a larger hybrid cloud.

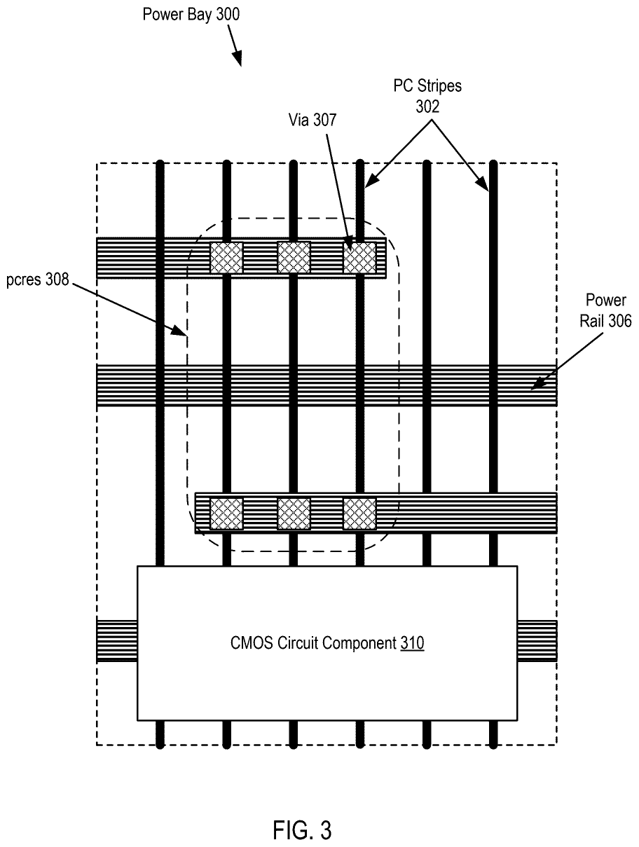

For further explanation, FIG. 3 sets forth a block diagram of an example power bay (or power grid) comprising a CMOS circuit integrating resistors using place and route methodology according to some embodiments of the present disclosure. The example of FIG. 3 shows a portion of a power bay 300 including a CMOS circuit, specifically depicting a portion of the power bay that comprises a resistor configured for seamless integration into a CMOS circuit and compatible with place and route methodologies. The example of FIG. 3 does not show a complete Power Bay, rather FIG. 3 shows only the horizontal lines (power rail 306) of the Power Grid on the relevant metal level (here M1), but does not show the vertical lines of the Power Grid on a next metal level (e.g., M2). Therefore, the vertical lines (pc stripes 302) shown in FIG. 3 are not BEOL power strips, but are poly silicon or pc stripes. The resistor shown in FIG. 3 is pcres 308, which is made up of multiple components, such as power rails 306, vias 307 placed on the power rails, where the top vias 307 connect to the bottom vias within the resistor through the pc stripes 302 within the pcres 308 portion of the power grid. The example pc stripes 302 are oriented vertically and the example power rails 306 are oriented horizontally across the power grid. The CMOS circuit is positioned on the power bay 300, however the example of FIG. 3 shows only a portion of the power bay and the included CMOS circuit. The CMOS circuit is made up of multiple components, one of which is shown in FIG. 3, such as CMOS circuit component 310. In one embodiment, the CMOS circuit component is a transistor, such as a p-fet or an n-fet. In the example of FIG. 3, the CMOS circuit component 310 shares the same tracks (i.e. power rails or stripes) as pcres 308.

In one embodiment, the place and route module 106 of FIG. 1 is configured to determine a layout for a pcres device (such as pcres 308) to include within the CMOS circuit in the power bay (such as power bay 300). The layout of the pcres device may be determined based on one or more layout parameters in order to reach a desired resistance value. That is, each layout parameter may be selected in order to achieve a certain resistance value for the pcres.

The layout parameters may include: a number of parallel rm stripes (pc stripes 302) included within the pcres (where adding more stripes increases the overall resistance of the pcres device); a length of stripes utilized in the pcres device (i.e. how many vertical levels or layers are traversed by the stripes from via to via); a meander length of the pcres device (described below), a selection of an implant (such as a CMOS circuit component that may be included under/across the pcres device and sharing power rails; and the selected resistive materials used in each of the components that make up the pcres device (such as the materials of the power stripes, the vias, the power rails, any implants, and the like). Each of the layout parameters may be selected in order to approximate a desired resistance value for the pcres device 308.

In the example of FIG. 3, the pcres 308 includes only straight pc stripes, with no meander included in the pcres device 308. However, in other embodiments (not shown in FIG. 3), the pcres device may include one or more meanders. An example pcres device including meanders would snake up and down across the power grid using pairs of vias, where the pcres tracks would match the shape of a square wave, having multiple segmented power rails for each given via pair.

In some embodiments, a pcres device (such as pcres 308) may include multiple tap points (not shown in FIG. 3) for coupling other parts of a circuit. In such embodiments, the multiple tap points provide for multiple possible resistance values (depending on which tap points are being used or coupled to) within a single pcres device. Such embodiments allow for a single pcres device within a circuit to provide a customized amount of resistance based on which tap points are used.

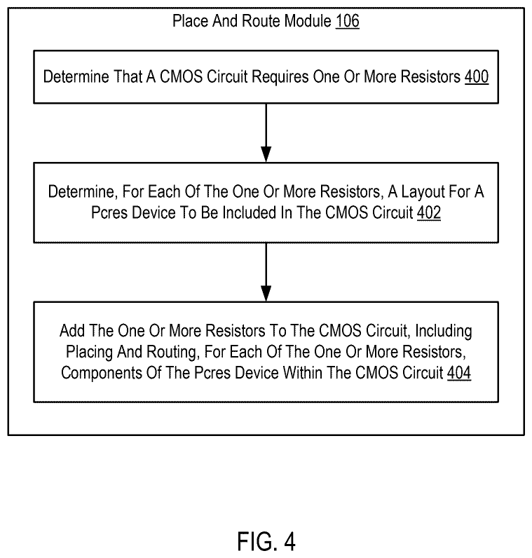

For further explanation, FIG. 4 sets forth a flow chart illustrating an exemplary method of place and route methodology integrating resistors into CMOS circuits according to embodiments of the present disclosure. The method of FIG. 4 includes determining 400 that a CMOS circuit requires one or more resistors. Determining 400 that a CMOS circuit requires one or more resistors may be carried out by place and route module 106 by referencing a design request, a specification, user input, or some other form of indication for the type of CMOS circuit being designed and which components are to be included within the design.

The method of FIG. 4 also includes determining 402, for each of the one or more resistors, a layout for a pcres device to include within the CMOS circuit. Determining 400 a layout for a pcres device to include within the CMOS circuit may be carried out by place and route module 106 by considering what resistor is needed for the design of the CMOS circuit and determining one or more pcres device components and their placement within the circuit to provide the needed resistor. Pcres devices may be made up of multiple components added to the power bay comprising the CMOS circuit, and the placement of each of these components may significantly impact the resulting resistance of the pcres device. Therefore, once a desired resistance value is determined, the place and route module 106 is configured to determine a layout for the pcres device to approximate the desired resistance.

The method of FIG. 4 also includes adding 404 the one or more resistors to the CMOS circuit, including placing and routing, for each of the one or more resistors, components of the pcrfes device within the CMOS circuit. Adding 404 the one or more resistors to the CMOS circuit may be carried out by place and route module 106 by determining the components to include for the pcres device, determining the placement of such components within the power bay, and determining the routing of the components and lines coupling the pcres device to other components of the CMOS circuit. In some embodiments, the pcres device is added to the power grid after the other CMOS components, before the CMOS components, or simultaneously with the CMOS components.

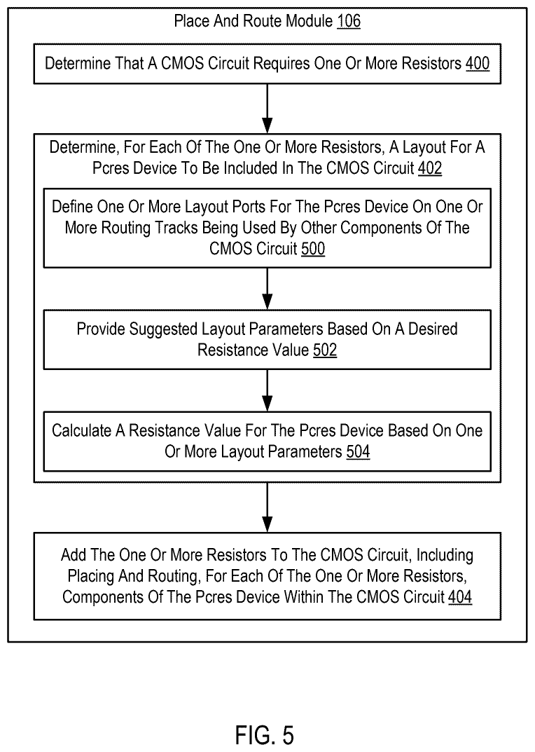

For further explanation, FIG. 5 sets forth a flow chart illustrating another exemplary method of place and route methodology integrating resistors into CMOS circuits according to embodiments of the present disclosure. The method of FIG. 5 differs from the method of FIG. 4 in that the method of FIG. 5 further includes, as part of determining 402 a layout for a pcres device to include within the CMOS circuit, defining 500 one or more layout ports for the pcres device on one or more routing tracks being used by other components of the CMOS circuit. Defining 500 one or more layout ports for the pcres device on one or more routing tracks (power grid rails/stripes) being used by other components of the CMOS circuit may be carried out by place and route module 106 by determining where the start and end portions of the pcres device should be positioned within the power grid and in relation to the various other components of the CMOS circuit. That is, the place and route module is configured to determine exactly where within the CMOS circuit the pcres device (or devices) are to be positioned.

The method of FIG. 5 also includes, as part of determining 402 a layout for a pcres device to include within the CMOS circuit, providing 502 suggested layout parameters based on a desired resistance value. Providing 502 suggested layout parameters based on a desired resistance value may be carried out by place and route module 106 by determining a desired resistance value for a given pcres device to be included in the CMOS circuit and then selecting one or more layout parameters (as described in reference to FIG. 3 above) to approximate the desired resistance. By selecting layout parameters, the place and route module is configured to design a layout for a pcres device that replaces a conventional RM resistor and that is designed to have a corresponding desired resistance value. In some embodiments, the place and route module references data that maps out resistance values based on each potential combination of layout parameters. For example, the place and route module may reference a table included in memory local to the module (not shown in FIG. 1) that includes each possible combination of various different layout parameters and an associated approximate resistance value, and then select the combination of layout parameters to reach a desired resistance value. In other embodiments, the place and route module is configured to store previously calculated (see below) resistance values and their corresponding layout parameters in order to select the layout parameters of a given pcres device.

The method of FIG. 5 also includes, as part of determining 402 a layout for a pcres device to include within the CMOS circuit, calculating 504 a resistance value for the pcres device based on one or more layout parameters. Calculating 504 a resistance value for the pcres device based on one or more layout parameters may be carried out by place and route module 106 after the layout has been determined. In one embodiment, the step of calculating 504 the resistance value of the pcres device is carried out after adding the pcres device to the CMOS circuit, which allows the place and route module to check the accuracy of the resistance value of the pcres device compared with its approximation made during the design of the layout. In some embodiments, the resistance value and the associated layout parameters are stored in memory for future reference to aid in future circuit designs.

In view of the explanations set forth above, readers will recognize that the benefits of place and route methodology integrating resistors into CMOS circuits according to embodiments of the present disclosure include:
Increasing circuit efficiency by allowing for CMOS style layouts that include resistors in a space-saving format without having to rely on less compact RM resistors.
Increasing design efficiency by allowing for automated place and route methods for designing CMOS circuits that include resistors.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

It will be understood from the foregoing description that modifications and changes may be made in various embodiments of the present disclosure without departing from its true spirit. The descriptions in this specification are for purposes of illustration only and are not to be construed in a limiting sense. The scope of the present disclosure is limited only by the language of the following claims.

What is claimed is:

1. A method of place and route methodology integrating polysilicon resistor (pcres) devices into complementary metal-oxide-semiconductor (CMOS) circuits, the method comprising:
determining, by a place and route module, that a CMOS circuit requires one or more resistors;
determining, by the place and route module for each of the one or more resistors, a layout for a pcres device to be included in the CMOS circuit; and
adding, by the place and route module and for each of the one or more resistors, the pcres device to the CMOS circuit, wherein the adding the pcres device includes placing and routing components of the pcres device within the CMOS circuit.

2. The method of claim 1, wherein the pcres device is added to a CMOS power grid bay, the CMOS power grid comprising the CMOS circuit.

3. The method of claim 1, wherein determining the layout for the pcres device includes defining one or more layout ports for the pcres device on one or more routing tracks being used by other components of the CMOS circuit.

4. The method of claim 1, wherein the layout of the pcres device is determined based on one or more layout parameters.

5. The method of claim 4, wherein the one or more layout parameters includes a number of parallel rm stripes and a meander length of the pcres device.

6. The method of claim 4, wherein the one or more layout parameters includes a selection of an implant to approximate a desired resistance value.

7. The method of claim 4, further comprising calculating a resistance value for the pcres device based on the one or more layout parameters.

8. The method of claim 1, wherein the place and route module is configured to provide suggested layout parameters based on a desired resistance value.

9. The method of claim 1, wherein the layout of the pcres device is determined based on a resistive material to be included within the one or more resistors.

10. A system for place and route methodology integrating polysilicon resistor (pcres) devices into complementary metal-oxide-semiconductor (CMOS) circuits, the system comprising:
a processor;
memory operatively coupled to the processor; and
a place and route module included within the memory and configured to:
determine that a CMOS circuit requires one or more resistors;
determine, for each of the one or more resistors, a layout for a pcres device to be included in the CMOS circuit; and
add, for each of the one or more resistors, the pcres device to the CMOS circuit, wherein the adding the pcres device includes placing and routing components of the pcres device within the CMOS circuit.

11. The system of claim 10, wherein the pcres device is added to a CMOS power grid bay, the CMOS power grid comprising the CMOS circuit.

12. The system of claim 10, wherein determining the layout for the pcres device includes defining one or more layout ports for the pcres device on one or more routing tracks being used by other components of the CMOS circuit.

13. The system of claim 10, wherein the layout of the pcres device is determined based on one or more layout parameters.

14. The system of claim 13, wherein the one or more layout parameters includes a number of parallel rm stripes and a meander length of the pcres device.

15. The system of claim 13, wherein the one or more layout parameters includes a selection of an implant to approximate a desired resistance value.

16. The system of claim 13, further comprising calculating a resistance value for the pcres device based on the one or more layout parameters.

17. The system of claim 10, wherein the layout of the pcres device is determined based on a resistive material to be included within the one or more resistors.

18. A computer program product comprising a computer readable storage medium and computer program instructions stored therein that, when executed, are configured to:
determine that a CMOS circuit requires one or more resistors;
determine, for each of the one or more resistors, a layout for a pcres device to be included in the CMOS circuit; and
add, for each of the one or more resistors, the pcres device to the CMOS circuit, wherein the adding the pcres device includes placing and routing components of the pcres device within the CMOS circuit.

19. The computer program product of claim 18, wherein the pcres device is added to a CMOS power grid bay, the CMOS power grid comprising the CMOS circuit.

20. The computer program product of claim 18, wherein the pcres device includes a plurality of tap points, wherein a resistance value of the pcres device depends on which tap points are being used.
